(19) United States
(12) Patent Application Publication
(10) Pub. No.: US 2026/0082719 A1
(43) Pub. Date: Mar. 19, 2026

(54) SOLID-STATE IMAGING ELEMENT AND MANUFACTURING METHOD, AND ELECTRONIC DEVICE

(71) Applicant: SONY SEMICONDUCTOR SOLUTIONS CORPORATION, KANAGAWA (JP)

(72) Inventor: TAKESHI ISHIZAKI, KANAGAWA (JP)

(21) Appl. No.: 19/106,244

(22) PCT Filed: Aug. 21, 2023
(86) PCT No.: PCT/JP2023/029937

§ 371 Date: Feb. 25, 2025

(30) Foreign Application Priority Data
Sep. 8, 2022 (JP) 2022-142692

(51) Int. Cl. H10F 39/00; H01L 23/522; H04N 25/771; H10D 1/00; H10D 1/68

(52) U.S. Cl. CPC H10F 39/811; H10D 1/042; H10D 1/716; H10W 20/496; H04N 25/771

(57) ABSTRACT

The present disclosure relates to a solid-state imaging element, a manufacturing method, and an electronic device that can achieve higher image quality. The solid-state imaging element includes a plurality of pixels, a capacitor provided for each of the pixels and formed in a three-dimensional shape between an upper wiring and a lower wiring of a wiring layer of the pixels, and an isolation unit that electrically isolates capacitors of adjacent pixels from each other. Then, the isolation unit is provided for each of the pixels so as to surround the capacitor, and an interlayer insulating film is provided between the isolation units of the respective pixels. The present technology can be applied to a CMOS image sensor, for example.

### TECHNICAL FIELD

The present disclosure relates to a solid-state imaging element and a manufacturing method, and an electronic device, and more particularly relates to a solid-state imaging element and a manufacturing method, and an electronic device capable of achieving higher image quality.

### BACKGROUND ART

Conventionally, since the area of a memory cell is reduced along with miniaturization of a dynamic random access memory (DRAM) element, development of a technique of increasing capacitance by forming a capacitor in a three-dimensional shape has been advanced.

For example, Patent Document 1 discloses a DRAM element having a configuration in which one memory cell area having a plurality of capacitor elements is isolated from a peripheral circuit area by a groove formed in a peripheral edge portion of the memory cell area.

### CITATION LIST

### Patent Document

Patent Document 1: Japanese Patent Application Laid-Open No. 2010-287716

### SUMMARY OF THE INVENTION

### Problems to be Solved by the Invention

By the way, for example, it has been studied to improve image quality by applying a capacitor having a three-dimensional shape used in the memory cell disclosed in Patent Document 1 described above to a complementary metal oxide semiconductor (CMOS) image sensor. However, since electrical isolation is not performed between capacitors of a three-dimensional shape, it is assumed that capacitors of three-dimensional shapes of adjacent pixels are electrically connected to each other, and it is difficult to apply the capacitor to a CMOS image sensor.

The present disclosure has been made in view of such a situation, and aims to achieve higher image quality.

### Solutions to Problems

A solid-state imaging element according to one aspect of the present disclosure includes a plurality of pixels, a capacitor provided for each of the pixels and formed in a three-dimensional shape between an upper wiring and a lower wiring of a wiring layer of the pixels, and an isolation unit that electrically isolates the capacitors of the pixels adjacent to each other.

A manufacturing method according to one aspect of the present disclosure includes forming a capacitor provided for each of a plurality of pixels and formed in a three-dimensional shape between an upper wiring and a lower wiring of a wiring layer of the pixels, and forming an isolation unit that electrically isolates the capacitors of the pixels adjacent to each other.

An electronic device according to one aspect of the present disclosure includes a solid-state imaging element including a plurality of pixels, a capacitor provided for each of the pixels and formed in a three-dimensional shape between an upper wiring and a lower wiring of a wiring layer of the pixels, and an isolation unit that electrically isolates the capacitors of the pixels adjacent to each other.

In one aspect of the present disclosure, a capacitor having a three-dimensional shape is provided between an upper wiring and a lower wiring of a wiring layer of pixels for each of a plurality of pixels, and capacitors of the pixels adjacent to each other are electrically isolated from each other by an isolation unit.

### BRIEF DESCRIPTION OF DRAWINGS

FIG. 1 is a circuit diagram illustrating an embodiment of a pixel included in an imaging element to which the present technology is applied.

FIG. 2 is a diagram illustrating a configuration example of an MIM capacitor in plan view.

FIG. 3 is a diagram illustrating a configuration example of the MIM capacitor in a cross-sectional view.

FIG. 4 is a diagram describing a first step.

FIG. 5 is a diagram describing a second step.

FIG. 6 is a diagram describing a third step.

FIG. 7 is a diagram describing a fourth step.

FIG. 8 is a diagram describing a fifth step.

FIG. 9 is a diagram describing a sixth step.

FIG. 10 is a diagram describing a seventh step.

FIG. 11 is a diagram describing an eighth step.

FIG. 12 is a cross-sectional view illustrating a modification of the MIM capacitor.

FIG. 13 is a block diagram illustrating a configuration example of an imaging device.

FIG. 14 is a diagram illustrating use examples of using an image sensor.

### MODE FOR CARRYING OUT THE INVENTION

Specific embodiments to which the present technology is applied will be described below in detail with reference to the drawings.

### <Configuration Example of Pixel>

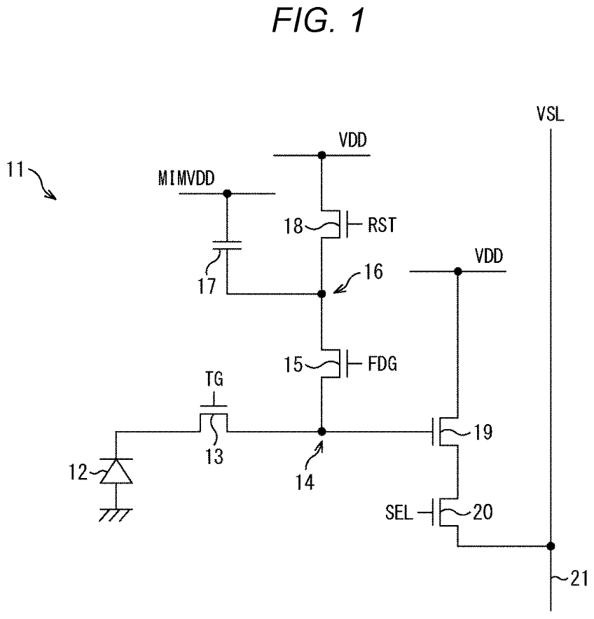

An embodiment of a pixel included in an imaging element to which the present technology is applied will be described with reference to FIGS. 1 to 3.

FIG. 1 illustrates a circuit diagram of a pixel 11.

As illustrated in FIG. 1, the pixel 11 includes a photoelectric conversion unit 12, a transfer transistor 13, a first floating diffusion (FD) unit 14, a connection transistor 15, a second FD unit 16, an MIM capacitor 17, a reset transistor 18, an amplification transistor 19, and a selection transistor 20, and outputs a pixel signal via a vertical signal line 21.

For example, the pixel 11 is a Lateral Over Flow Integration Capacitor (LOFIC) pixel, and has a structure in which electric charge overflowing from the photoelectric conversion unit 12 is guided in a lateral direction and accumulated in the MIM capacitor 17 in a case where light that exceeds a saturation capacitance of the photoelectric conversion unit 12 is irradiated.

The photoelectric conversion unit 12 has an anode terminal grounded and a cathode terminal connected to the first FD unit 14 via the transfer transistor 13. Then, the photoelectric conversion unit 12 receives light emitted to a light receiving surface of the imaging element, and photoelectrically converts the light into an electric charge corresponding to the amount of the light.

The transfer transistor 13 is disposed so as to connect the photoelectric conversion unit 12 and the first FD unit 14.

Then, the transfer transistor 13 is driven according to a transfer signal TG, and transfers the charge photoelectrically converted by the photoelectric conversion unit 12 to the first FD unit 14.

The first FD unit 14 accumulates the charge transferred from the photoelectric conversion unit 12 via the transfer transistor 13 in order to convert the charge into a pixel signal.

The connection transistor 15 is arranged to connect the first FD unit 14 and the second FD unit 16. Then, the connection transistor 15 is driven according to the connection signal FDG, and turns on/off the connection between the first FD unit 14 and the second FD unit 16.

The second FD unit 16 is connected to the first FD unit 14 in a state where the connection transistor 15 is turned on, and accumulates charges together with the first FD unit 14.

The MIM capacitor 17 is a capacitor having a metal-insulator-metal (MIM) structure provided in the wiring layer of the imaging element, and is arranged to connect the second FD unit 16 and a signal wiring MIMVDD. Then, the MIM capacitor 17 accumulates charges similarly to the second FD unit 16.

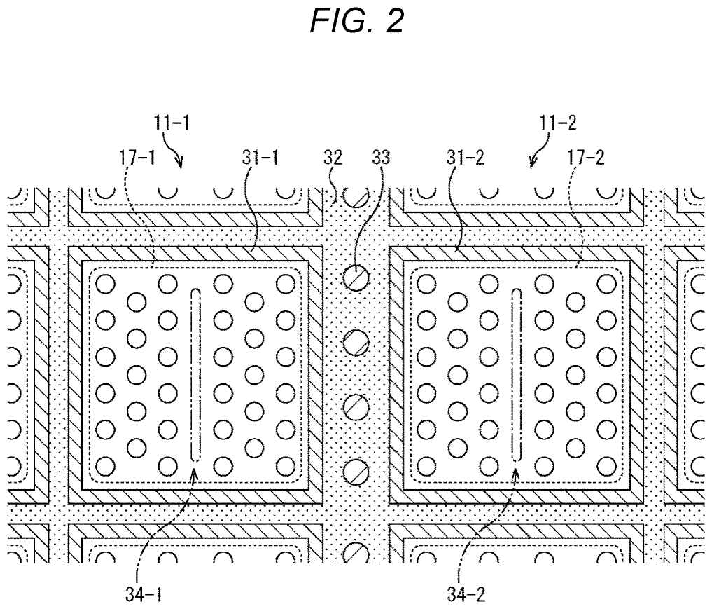

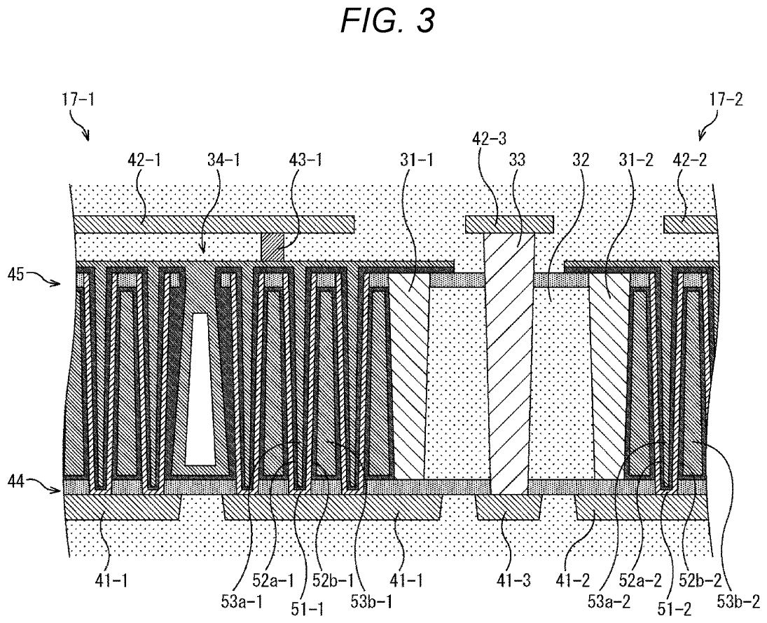

Furthermore, the MIM capacitor 17 has a structure having a plurality of cylinder shapes (as described later with reference to FIGS. 2 and 3, a shape in which a dielectric film is sandwiched between a cylindrical upper electrode and a cylindrical lower electrode).

The reset transistor 18 is disposed so as to connect the second FD unit 16 and a power supply wiring VDD. Then, the reset transistor 18 is driven according to a reset signal RST, and when the connection transistor 15 and the reset transistor 18 are turned on, the charges accumulated in the first FD unit 14, the second FD unit 16, and the MIM capacitor 17 are discharged to the power supply wiring VDD, and the charges are reset.

The amplification transistor 19 is disposed so that the first FD unit 14 is connected to the gate electrode, and the power supply wiring VDD and the selection transistor 20 are connected. Then, the amplification transistor 19 converts the charge accumulated by the first FD unit 14 or the charge accumulated by the first FD unit 14, the second FD unit 16, and the MIM capacitor 17 into a pixel signal at a level corresponding to the charge with respect to each capacitance.

The selection transistor 20 is disposed so as to connect the amplification transistor 19 and the vertical signal line 21. Then, the selection transistor 20 is driven in accordance with a selection signal SEL, and the pixel signal converted by the amplification transistor 19 is output to the vertical signal line 21 while the selection transistor 20 is on.

For example, in the pixel 11, in a case where the connection transistor 15 is turned off according to the connection signal FDG, the charge transferred from the photoelectric conversion unit 12 via the transfer transistor 13 is accumulated in the capacitance of only the first FD unit 14. Furthermore, in a case where the connection transistor 15 is turned on according to the connection signal FDG, the charge transferred from the photoelectric conversion unit 12 via the transfer transistor 13 is accumulated in the capacitance obtained by combining the first FD unit 14, the second FD unit 16, and the MIM capacitor 17. As described above, the pixel 11 having the structure in which the MIM capacitor 17 is provided can switch the capacitance for accumulating the charge transferred from the photoelectric conversion unit 12.

A configuration example of the MIM capacitor 17 will be described with reference to FIGS. 2 and 3.

FIG. 2 illustrates a schematic configuration example in which the MIM capacitors 17-1 and 17-2 included in the two adjacent pixels 11-1 and 11-2 are viewed in a plan view. Note that the pixels 11-1 and 11-2 are similarly configured, and are simply referred to as a pixel 11 in a case where it is not necessary to distinguish them, and each unit constituting the pixel 11 is also similarly referred to.

As described above, the MIM capacitor 17 has a structure having a plurality of cylinder shapes, and in FIG. 2, a plurality of circles illustrated in a region surrounded by a broken line representing the MIM capacitor 17 represents a plurality of cylinder shapes. Note that the cylinder shape of the MIM capacitor 17 is not limited to the circular shape, and may be, for example, a rectangular shape.

Then, the pixel 11 is configured by providing an isolation structure 31 so as to surround an outer periphery of the MIM capacitor 17, and an interlayer insulating film 32 is provided between the isolation structures 31. Thus, the MIM capacitors 17 of the adjacent pixels 11 are electrically and physically isolated from each other by the isolation structure 31 and the interlayer insulating film 32. That is, as illustrated, the MIM capacitor 17-1 of the pixel 11-1 and the MIM capacitor 17-2 of the pixel 11-2 are isolated by the isolation structures 31-1 and 31-2 and the interlayer insulating film 32.

Furthermore, a through electrode 33 is disposed between the pixels 11 so as to penetrate the interlayer insulating film 32.

Furthermore, as described later with reference to FIG. 3, the pixel 11 is provided with a slit 34.

FIG. 3 illustrates a schematic configuration example in which MIM capacitors 17-1 and 17-2 included in two adjacent pixels 11-1 and 11-2 are viewed in cross section.

As illustrated in FIG. 3, the MIM capacitor 17 is formed in a three-dimensional shape between a lower wiring 41 and an upper wiring 42, and the MIM capacitor 17 and the upper wiring 42 are connected via an electrode 43. For example, the MIM capacitor 17 is disposed in a wiring layer (a wiring layer on either the sensor substrate side or the logic substrate side) of the pixel 11. In addition, an insulating film 44 is provided at a lower end portion of the MIM capacitor 17, and an insulating film 45 is provided at an upper end portion of the MIM capacitor 17.

For example, silicon nitride can be used for the insulating film 44 and the insulating film 45. Furthermore, the insulating film 45 is formed to be partially opened by the slit 34.

The MIM capacitor 17 is configured by providing upper electrodes 53a and 53b so as to face both surfaces of the lower electrode 51, respectively. Then, the MIM capacitor 17 is configured so that a dielectric film 52a is sandwiched between one surface of the lower electrode 51 and the upper electrode 53a, and a dielectric film 52b is sandwiched between the other surface of the lower electrode 51 and the upper electrode 53b.

Furthermore, the lower electrode 51 is connected to the lower wiring 41, and the upper electrodes 53a and 53b are connected to the upper wiring 42 via the electrode 43.

For example, the MIM capacitor 17 is configured so that the lower electrode 51 is formed in a concave shape along each of the recesses having a high aspect ratio constituting the cylinder shape, the dielectric film 52a is formed inside the lower electrode 51, and the upper electrode 53a is embedded inside the dielectric film 52a. Moreover, the MIM capacitor 17 is configured so that the dielectric film 52b is formed outside each of the lower electrodes 51 constituting the cylinder shape, and the upper electrode 53b is embedded outside the dielectric film 52b between the adjacent cylinder shapes. For example, titanium nitride can be used for the lower electrode 51 and the upper electrode 53, and a High-k film (for example, a ZrO/AlO/ZrO stacked film) can be used for the dielectric film 52.

The isolation structure 31 is provided on the outer periphery of the MIM capacitor 17, and an interlayer insulating film 32 is provided between the adjacent isolation structures 31.

The isolation structure 31 is configured by embedding a material having a selection ratio with respect to SiO2 constituting the interlayer insulating film 32 in a trench formed penetrating the interlayer insulating film 32 by wet etching so as to surround the MIM capacitor 17. For example, silicon nitride, silicon carbide, or the like (SiN, SiC(N) film) can be used as a material constituting the isolation structure 31. Furthermore, as a material constituting the isolation structure 31, a metal (for example, Ti, Ta, W, Mo, Al, Cu, Co, Ni, Ru, and the like) or a compound containing these metals (for example, TiN, TaN, WN, and MoN) may be used.

The through electrode 33 is provided between the MIM capacitors 17, and a lower wiring 41-3 and an upper wiring 42-3 are electrically connected by the through electrode 33. For example, tungsten can be used as a material constituting the through electrode 33.

The pixel 11 configured as described above can electrically isolate the MIM capacitor 17 from another adjacent pixel 11. That is, even when the MIM capacitor 17 is applied to a CMOS image sensor, conduction between the MIM capacitors 17 can be avoided. Furthermore, by adopting the MIM capacitor 17 having a three-dimensional structure using a cylinder shape, the pixel 11 can achieve higher capacitance than, for example, the MIM capacitor having a two-dimensional structure.

Thus, the imaging element including the pixels 11 can expand a dynamic range at the time of capturing a high dynamic range (HDR) image, for example, and can capture an image with higher image quality.

### <Manufacturing Method of Imaging Element>

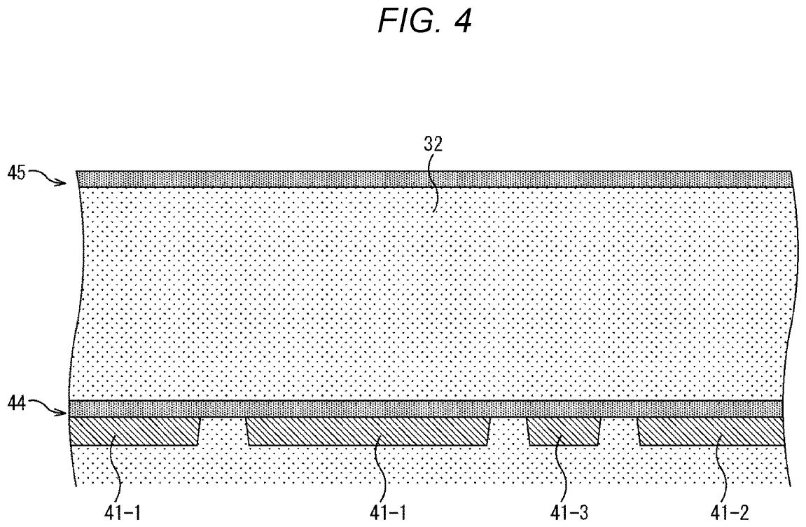

Steps of forming the MIM capacitor 17 in the method of manufacturing the imaging element will be described with reference to FIGS. 4 to 11.

In a first step, as illustrated in FIG. 4, the lower wiring 41 and the insulating film 44 are formed on the lower side of the interlayer insulating film 32, and the insulating film 45 is formed on the upper side of the interlayer insulating film 32.

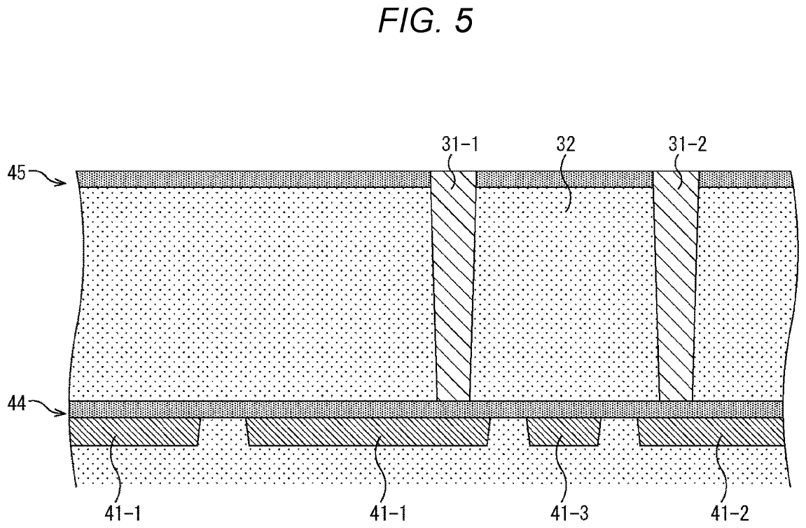

In a second step, as illustrated in FIG. 5, the isolation structure 31 is formed by embedding a material having a selection ratio with SiO2 as described above in a trench formed by wet etching up to the insulating film 44 so as to open the insulating film 45 and penetrate the interlayer insulating film 32.

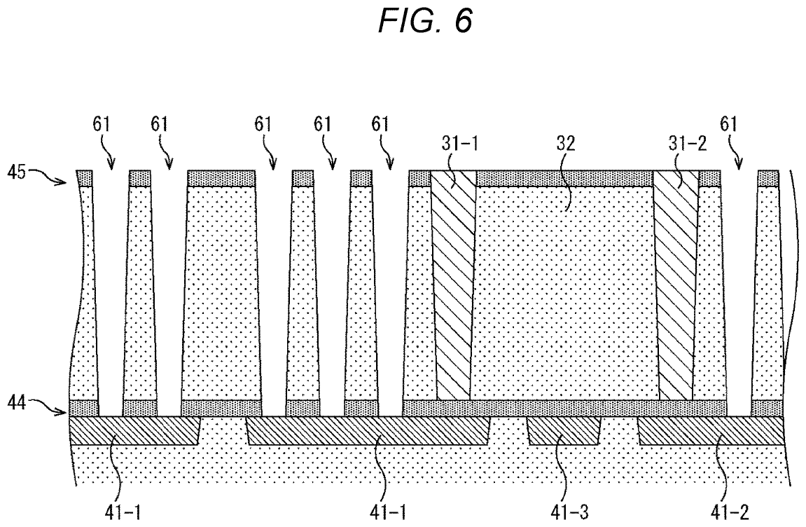

In a third step, as illustrated in FIG. 6, a plurality of recesses 61 for forming the cylinder shape of the MIM capacitor 17 is formed so as to penetrate the interlayer insulating film 32, the insulating film 44, and the insulating film 45. That is, the plurality of recesses 61 is formed so that the lower wiring 41 is exposed on respective bottom surfaces.

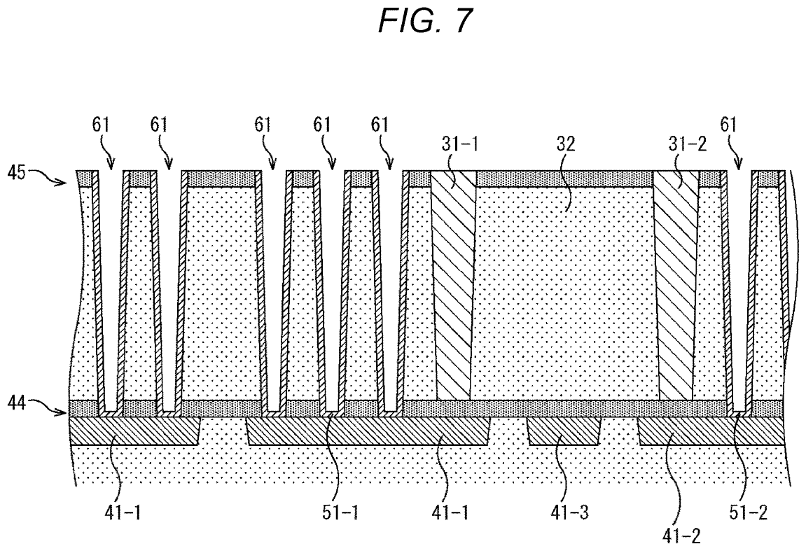

In a fourth step, as illustrated in FIG. 7, a plurality of lower electrodes 51 is formed by forming a film of titanium nitride on the side surface and the bottom surface of each of the plurality of recesses 61. That is, the lower electrode 51 is formed in a concave shape along the shape of the recess 61.

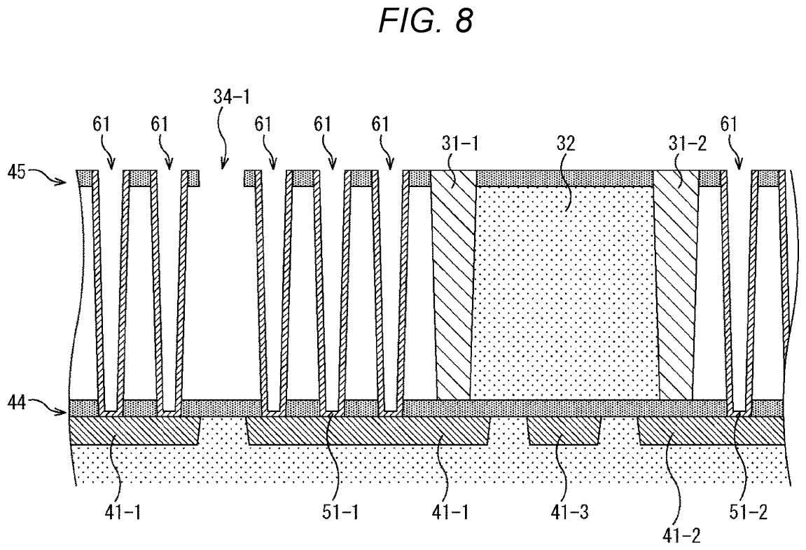

In a fifth step, as illustrated in FIG. 8, after the slit 34 is processed with respect to the insulating film 45, the interlayer insulating film 32 is selectively etched back to remove the interlayer insulating film 32 inside the isolation structure 31. That is, the interlayer insulating film 32 between the plurality of lower electrodes 51 is removed via the slit 34 so that only the interlayer insulating film 32 between the adjacent interlayer insulating films 32 remains. At this time, an upper end of each of the lower electrodes 51 is supported by the insulating film 45.

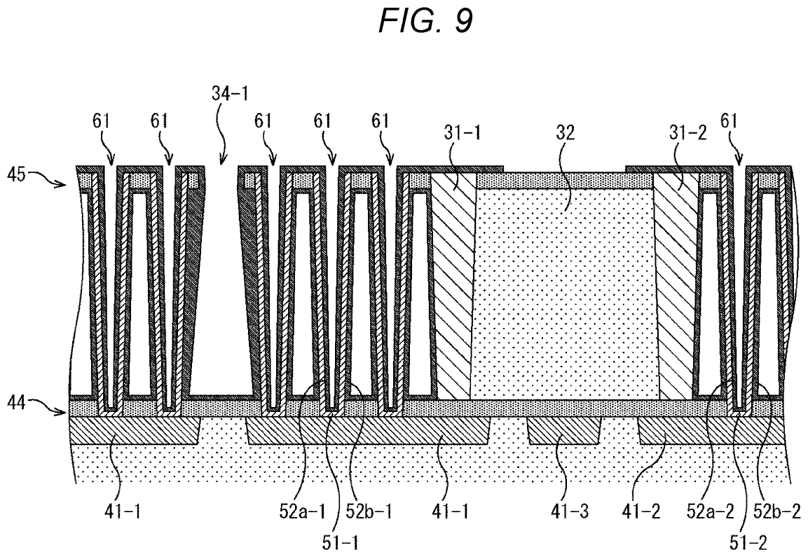

In a sixth step, as illustrated in FIG. 9, a dielectric is formed on both surfaces of the lower electrode 51. Thus, the dielectric film 52a is formed on the inside of the recessed shape of the lower electrode 51, and the dielectric film 52b is formed on the outside of the recessed shape of the lower electrode 51.

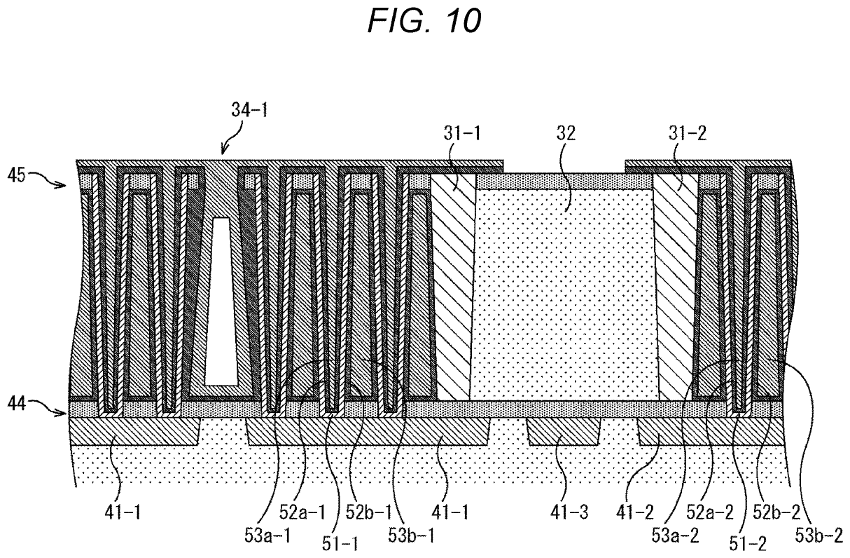

In a seventh step, as illustrated in FIG. 10, titanium nitride is deposited on both surfaces of the lower electrode 51. Thus, the upper electrode 53a is formed so as to sandwich the dielectric film 52a with the lower electrode 51, and the upper electrode 53b is formed so as to sandwich the dielectric film 52b with the lower electrode 51.

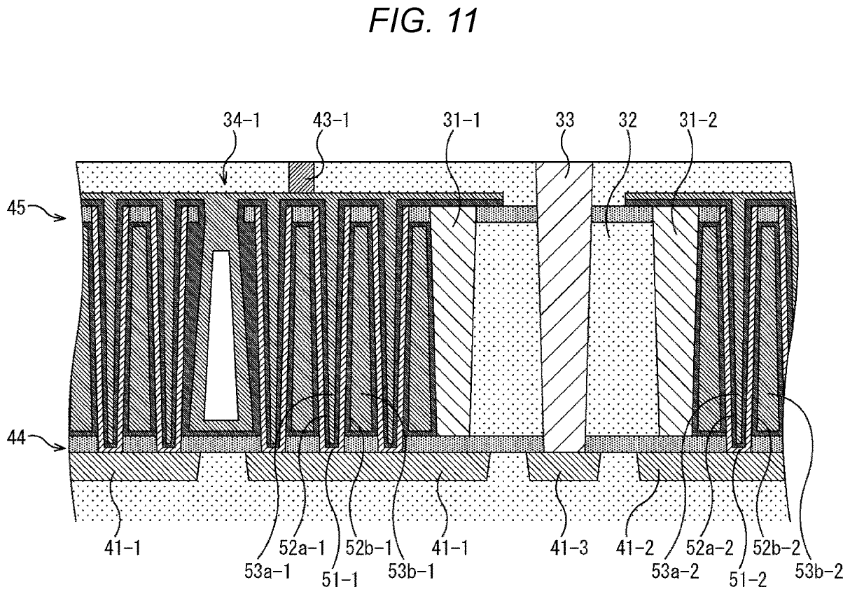

In the eighth step, as illustrated in FIG. 11, after the interlayer insulating films 32 are stacked and increased, tungsten is buried in a trench formed between the adjacent isolation structures 31 so as to penetrate the interlayer insulating film 32, the insulating film 44, and the insulating film 45 until the lower wiring 41-3 is exposed, thereby forming the through electrode 33. Furthermore, the electrode 43 is formed so as to be connected to the upper electrode 53a.

Thereafter, the upper wiring 42 is formed so as to be connected to each of the electrode 43 and the through electrode 33, thereby forming the MIM capacitor 17 as illustrated in FIG. 3 described above.

The MIM capacitor 17 formed by the above process can improve mechanical strength, for example, by supporting each of the lower electrodes 51 by the insulating film 45. Furthermore, when the interlayer insulating film 32 is selectively etched back, the etching can be stopped by the isolation structure 31.

### <Modification of MIM Capacitor>

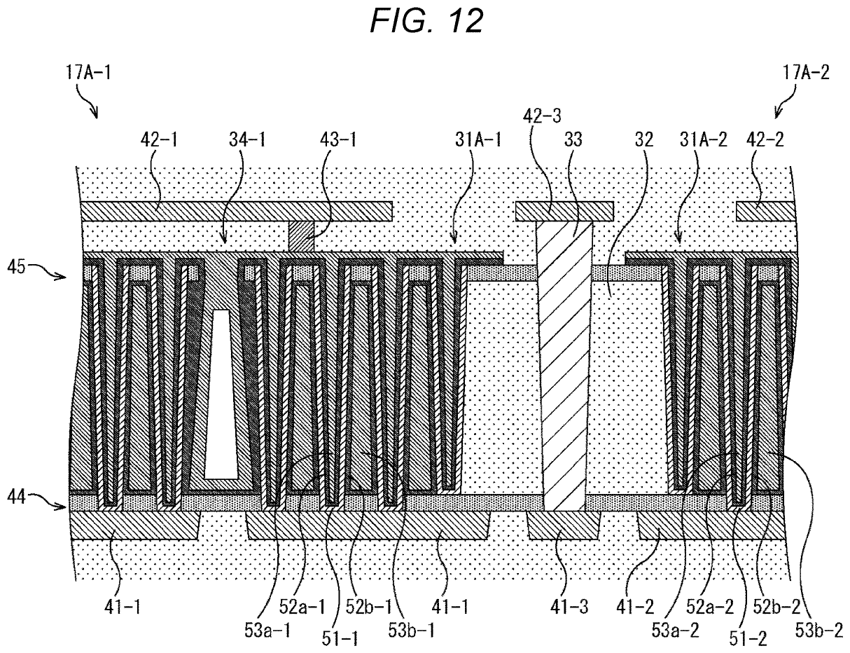

FIG. 12 is a cross-sectional view illustrating an example of a modification of the MIM capacitor 17.

As described above, in the MIM capacitor 17 illustrated in FIG. 3, the isolation structure 31 is configured by embedding a material having a selection ratio with SiO2 constituting the interlayer insulating film 32 in a trench formed to penetrate the interlayer insulating film 32.

On the other hand, in the MIM capacitor 17A illustrated in FIG. 12, the isolation structure 31A is formed by the same material as the lower electrode 51, the upper electrode 53a, and the dielectric film 52a. That is, in the MIM capacitor 17A, the isolation structure 31A is configured by a stacked structure in which a metal forming the lower electrode 51, a dielectric forming the dielectric film 52a, and a metal forming the upper electrode 53a are stacked.

Thus, a step only for forming the isolation structure 31 is unnecessary, and the isolation structure 31A can be formed simultaneously in the step of forming the lower electrode 51, the upper electrode 53a, and the dielectric film 52a. That is, a trench for forming the isolation structure 31A is formed simultaneously with the plurality of recesses 61 (see FIG. 6) for forming the cylinder shape of the MIM capacitor 17A. Then, when the lower electrode 51, the upper electrode 53a, and the dielectric film 52a are formed, a metal for forming the lower electrode 51, a dielectric for forming the dielectric film 52a, and a metal for forming the upper electrode 53a are stacked on the trench to form the isolation structure 31A.

As described above, the MIM capacitor 17A can constitute the isolation structure 31 by a part of the outer periphery thereof, and for example, cost reduction can be achieved by reducing the number of manufacturing processes.

Note that, as described above, the present technology is not limited to being applied to the MIM capacitor 17 used for switching the capacitance for accumulating the charge transferred from the photoelectric conversion unit 12, and may be applied to the MIM capacitor used for other applications in the pixel 11.

### <Configuration Example of Electronic Device>

The imaging element including the pixels 11 as described above can be applied to various electronic devices including, for example, an imaging system such as a digital still camera or a digital video camera, a mobile phone having an imaging function, or another device having an imaging function.

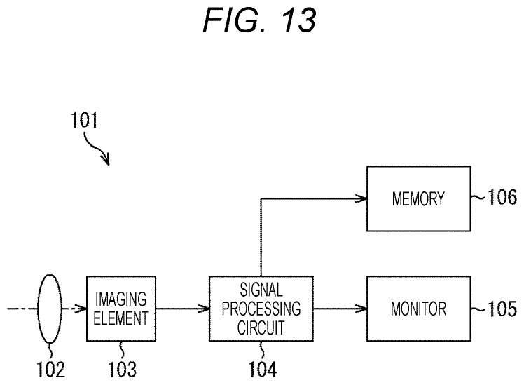

FIG. 13 is a block diagram illustrating a configuration example of an imaging device mounted on an electronic device.

As illustrated in FIG. 13, an imaging device 101 includes an optical system 102, an imaging element 103, a signal processing circuit 104, a monitor 105, and a memory 106, and can capture a still image and a moving image.

The optical system 102 includes one or more lenses, guides image light (incident light) from a subject to the imaging element 103, and forms an image on a light-receiving surface (sensor unit) of the imaging element 103.

As the imaging element 103, an imaging element including the pixels 11 described above is applied. Electrons are accumulated in the imaging element 103 for a certain period in accordance with the image formed on the light-receiving surface via the optical system 102. Then, a signal corresponding to the electrons accumulated in the imaging element 103 is supplied to the signal processing circuit 104.

The signal processing circuit 104 performs various types of signal processing on a pixel signal output from the imaging element 103. An image (image data) obtained by the signal processing performed by the signal processing circuit 104 is supplied to the monitor 105 to be displayed or supplied to the memory 106 to be stored (recorded).

In the imaging device 101 configured as described above, for example, a higher-quality image can be captured by applying the imaging element including the pixel 11 described above.

### <Use Example of Image Sensor>

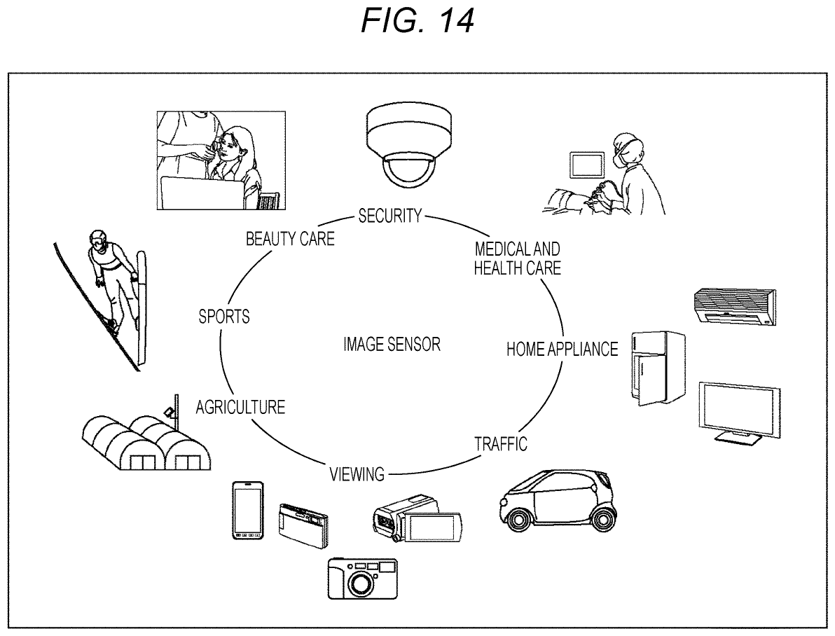

FIG. 14 is a diagram illustrating a use example of the above-described image sensor (imaging element).

The image sensor described above can be used in various cases for sensing light such as visible light, infrared light, ultraviolet light, and X-ray as described below, for example.
A device that captures an image to be used for viewing, such as a digital camera and a portable device with a camera function
A device for traffic purpose such as an in-vehicle sensor that captures images of the front, rear, surroundings, interior, and the like of an automobile, a monitoring camera for monitoring traveling vehicles and roads, and a ranging sensor that measures a distance between vehicles and the like for safe driving such as automatic stop, recognition of a driver's condition, and the like
A device for home appliance such as a television, a refrigerator, and an air conditioner that captures an image of a user's gesture and performs a device operation according to the gesture
A device used for medical and health care such as an endoscope and a device that performs angiography by receiving infrared light
A device used for security such as a security monitoring camera and an individual authentication camera
A device used for beauty care such as a skin measuring instrument for capturing images of skin and a microscope for capturing images of the scalp
A device used for sport such as an action camera or a wearable camera for sports applications or the like
A device used for agriculture such as a camera for monitoring conditions of fields and crops

### <Combination Example of Configuration>

Note that the present technology can also have the following configurations.

(1)

A solid-state imaging element including:
a plurality of pixels;
a capacitor provided for each of the pixels and formed in a three-dimensional shape between an upper wiring and a lower wiring of a wiring layer of the pixels; and
an isolation unit that electrically isolates the capacitors of the pixels adjacent to each other.
   (2)

The solid-state imaging element according to (1) above, in which
the isolation unit is provided for each of the pixels so as to surround the capacitor, and
an interlayer insulating film is provided between the isolation units of the respective pixels.
   (3)

The solid-state imaging element according to (2) above, further including:
a through electrode that penetrates the interlayer insulating film between the isolation units and connects the upper wiring and the lower wiring.
   (4)

The solid-state imaging element according to (2) or (3) above, in which
the isolation unit is formed by embedding a material having a selection ratio with the interlayer insulating film in a trench.
   (5)

The solid-state imaging element according to (4) above, in which
silicon nitride or silicon carbide is used as the material.
   (6)

The solid-state imaging element according to (4) above, in which
a metal or a compound containing the metal is used as the material.
   (7)

The solid-state imaging element according to any one of (1) to (6) above, in which
the capacitor has a plurality of cylinder shapes in which a dielectric film is sandwiched between a cylindrical upper electrode connected to the upper wiring and a cylindrical lower electrode connected to the lower wiring.
   (8)

The solid-state imaging element according to (7) above, in which
the capacitor is constituted by forming the dielectric film on both surfaces of the recessed lower electrode formed along each of the recesses having a high aspect ratio constituting the cylinder shape, and providing the upper electrode so as to sandwich each of the dielectric films.
   (9)

The solid-state imaging element according to (7) or (8) above, in which
an upper end of each of the lower electrodes constituting the cylinder shape is supported by an insulating film.
   (10)

The solid-state imaging element according to any one of (7) to (9) above, in which
the isolation unit is formed with a stacked structure in which same materials as materials of the upper electrode, the lower wiring, and the dielectric film constituting the capacitor are stacked.
   (11)

A manufacturing method of a solid-state imaging element, the method including:
forming a capacitor provided for each of a plurality of pixels and formed in a three-dimensional shape between an upper wiring and a lower wiring of a wiring layer of the pixels; and forming an isolation unit that electrically isolates the capacitors of the pixels adjacent to each other.
   (12)

An electronic device including a solid-state imaging element including:
a plurality of pixels;
a capacitor provided for each of the pixels and formed in a three-dimensional shape between an upper wiring and a lower wiring of a wiring layer of the pixels; and
an isolation unit that electrically isolates the capacitors of the pixels adjacent to each other.

Note that, the present embodiment is not limited to the embodiments described above, and various alterations can be made without departing from the gist of the present disclosure. Furthermore, the effects described herein are merely examples and are not restrictive, and there may be other effects.

### REFERENCE SIGNS LIST

11 Pixel
12 Photoelectric conversion unit
13 Transfer transistor
14 First FD unit
15 Connection transistor
16 Second FD unit
17 MIM capacitor
18 Reset transistor
19 Amplification transistor
20 Selection transistor
21 Vertical signal line
31 Isolation structure
32 Interlayer insulating film
33 Through electrode
34 Slit
41 Lower wiring
42 Upper wiring
43 Electrode
44 and 45 Insulating film
51 Lower electrode
52 Dielectric film
53 Upper electrode

1. A solid-state imaging element comprising:
a plurality of pixels;
a capacitor provided for each of the pixels and formed in a three-dimensional shape between an upper wiring and a lower wiring of a wiring layer of the pixels; and
an isolation unit that electrically isolates the capacitors of the pixels adjacent to each other.

2. The solid-state imaging element according to claim 1, wherein
the isolation unit is provided for each of the pixels so as to surround the capacitor, and
an interlayer insulating film is provided between the isolation units of the respective pixels.

3. The solid-state imaging element according to claim 2, further comprising:
a through electrode that penetrates the interlayer insulating film between the isolation units and connects the upper wiring and the lower wiring.

4. The solid-state imaging element according to claim 2, wherein
the isolation unit is formed by embedding a material having a selection ratio with the interlayer insulating film in a trench.

5. The solid-state imaging element according to claim 4, wherein
silicon nitride or silicon carbide is used as the material.

6. The solid-state imaging element according to claim 4, wherein
a metal or a compound containing the metal is used as the material.

7. The solid-state imaging element according to claim 1, wherein
the capacitor has a plurality of cylinder shapes in which a dielectric film is sandwiched between a cylindrical upper electrode connected to the upper wiring and a cylindrical lower electrode connected to the lower wiring.

8. The solid-state imaging element according to claim 7, wherein
the capacitor is constituted by forming the dielectric film on both surfaces of the recessed lower electrode formed along each of the recesses having a high aspect ratio constituting the cylinder shape, and providing the upper electrode so as to sandwich each of the dielectric films.

9. The solid-state imaging element according to claim 7, wherein
an upper end of each of the lower electrodes constituting the cylinder shape is supported by an insulating film.

10. The solid-state imaging element according to claim 7, wherein
the isolation unit is formed with a stacked structure in which same materials as materials of the upper electrode, the lower wiring, and the dielectric film constituting the capacitor are stacked.

11. A manufacturing method of a solid-state imaging element, the method comprising:
forming a capacitor provided for each of a plurality of pixels and formed in a three-dimensional shape between an upper wiring and a lower wiring of a wiring layer of the pixels; and
forming an isolation unit that electrically isolates the capacitors of the pixels adjacent to each other.

12. An electronic device comprising a solid-state imaging element comprising:
a plurality of pixels;
a capacitor provided for each of the pixels and formed in a three-dimensional shape between an upper wiring and a lower wiring of a wiring layer of the pixels; and
an isolation unit that electrically isolates the capacitors of the pixels adjacent to each other.
